(19) United States
(12) Patent Application Publication
(10) Pub. No.: US 2025/0364424 A1
(43) Pub. Date: Nov. 27, 2025

(54) INTERPOSER

(71) Applicant: Microsoft Technology Licensing, LLC, Redmond, WA (US)

(72) Inventors: Vasily LYUTSAREV, Cambridge (GB); Kai SHI, Cambridge (GB); Paolo COSTA, London (GB); Daniel Jonathan Finchley CLETHEROE, Cambridge (GB); Kaoutar BENYAHYA, Cambridge (GB); Junyi LIU, Cambridge (GB); Ariel GOMEZ DIAZ, Cambridge (GB); Shawn Yohanes SIEW, Cambridge (GB)

(21) Appl. No.: 18/946,911

(22) Filed: Nov. 13, 2024

Related U.S. Application Data
(60) Provisional application No. 63/651,898, filed on May 24, 2024.

(51) Int. Cl. H01L 23/538; H01L 25/00; H01L 25/065

(52) U.S. Cl. CPC H01L 23/5386; H01L 25/0655; H01L 25/50

(57) ABSTRACT

An interposer comprising: a first pair of connections, wherein a first connection of the first pair of connections is positioned above a second connection of the first pair of connections; a second pair of connections, wherein a first connection of the second pair of connections is positioned above a second connection of the second pair of connections; a ground trace between the first pair of connections and the second pair of connections.

### BACKGROUND

High-speed arrayed devices are gaining importance in optical communications, as a different method for creating high-bandwidth links. Each individual element in the array has its own data stream, and requires individual addressing and control, and all elements can be controlled as such simultaneously. To facilitate this, an interposer is often required to provide individual connectivity from the analogue front end to each arrayed device.

Some examples described herein provide an interposer design with high density, low cross-talk and/or low impedance. Some examples may be used for individually addressable high-speed arrayed devices using optical communications.

### SUMMARY

According to one aspect disclosed herein, there is provided an interposer comprising: comprising: a first pair of connections, wherein a first connection of the first pair of connections is positioned above a second connection of the first pair of connections; a second pair of connections, wherein a first connection of the second pair of connections is positioned above a second connection of the second pair of connections; a ground trace between the first pair of connections and the second pair of connections.

In some examples, a pair of connections may comprise a pair of differential signal traces. In other examples, a pair of connections may comprise a single-ended trace and a ground connection.

According to another aspect provided herein, there is provided a method of routing a rectangular array of devices to an interposer, the interposer comprising pads at four edges of the interposer, the method comprising: dividing the array of devices into rotationally symmetric quadrants; and for each rotationally symmetric quadrant: routing contacts of each device of a first row of devices in the quadrant in a first column comprising a straight line having the shortest route to a respective pad at an edge of the interposer, wherein the first row is closest to an outside edge of the rectangular array of devices; and then: a) routing a contact of each device of a next row of devices closest to the edge of the array to a column on a first side of the first column and adjacent and outside of the previous column on the first side of the device to a respective pad at the edge of the interposer; b) routing a contact of each device of a next row of devices closest to the edge of the array to a column on a second side of the first column and adjacent and outside of the previous column on the second side of the device to a respective pad at the edge of the interposer; repeating a) and b) until a device closest to the centre of the array of devices is reached, and then routing the contact for the device closest to the centre using a column furthest to the left or furthest to the right to a pad at the edge of the interposer. A corresponding apparatus is also provided.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of the present disclosure and to show how embodiments may be put into effect, reference is made by way of example to the accompanying drawings in which:

FIG. 1 is a diagram of an array of devices and an interposer in side view;

FIG. 2 is a diagram an array of devices and an interposer in top view;

FIG. 3A is a diagram showing rotationally symmetric quadrants for an array of devices, where the array has an even number of devices;

FIG. 3B is a diagram showing a routing method for the array of devices in FIG. 3A;

FIG. 4A is a diagram showing rotationally symmetric quadrants for an array of devices, where the array has an odd number of devices;

FIG. 4B is a diagram showing a routing method for the array of devices in FIG. 4A;

FIG. 5 shows an interposer design;

FIG. 6A shows a cross section of a design for traces connecting an interposer to an array of devices;

FIG. 6B shows a perspective view of the design in FIG. 6A;

FIG. 7A shows a cross section of a design for traces connecting an interposer to an array of devices;

FIG. 7B shows a perspective view of the design in FIG. 7A;

FIG. 8 is a flow chart describing a method disclosed herein.

### DETAILED DESCRIPTION OF EMBODIMENTS

An interposer can be used to provide individual connectivity to each arrayed device in an array of devices. In some examples, an interposer can be considered to comprise an electrical interface.

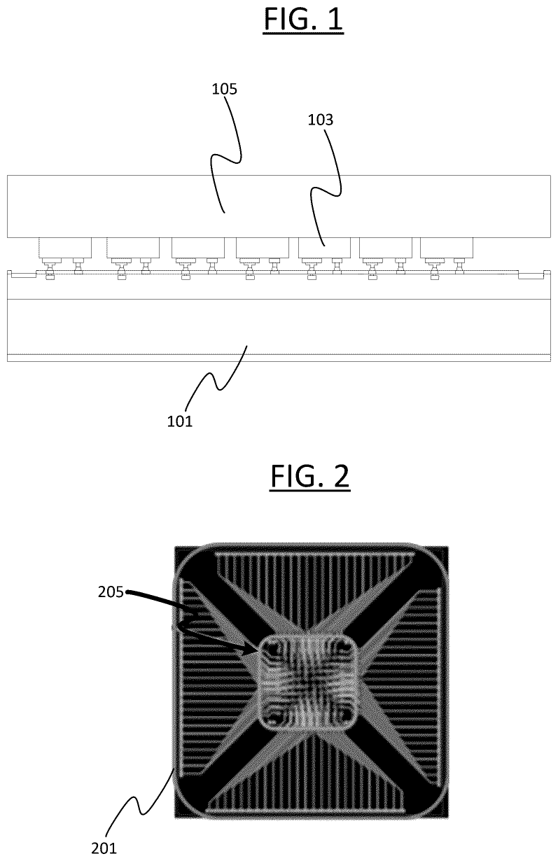

An example of a subassembly including an interposer 101 and an array 105 of devices is shown in FIG. 1, which shows a side view. An array of devices 105 including device 103 is connected to interposer 101. Examples of devices that may be included in an array include emitters (arrayed lasers or Light Emitting Diodes (LEDs) and receiver (photodiodes or photodetectors). In some examples, device 103 may comprise an emitter (e.g., arrayed lasers or Light Emitting Diodes (LEDs)) or a receiver (e.g., a photodiode or a photodetector).

FIG. 2 shows a top view of the system such as the system of FIG. 1. The central square 205 indicates the position of the array of devices, and the interposer is bound by the outer square 201. Each of the devices in the array 205 has a contact (represented by a line in FIG. 2) to a pad at the edge of the interposer (at the edges of the outer square 201).

There are design challenges to consider for interposer. High density interposers that are able to connect to a high number of devices per unit area lead to higher data-rate per unit area and reduced cost. Further, to maximise channel performance without compromising signal integrity, minimizing cross-talk between channels in the interposer increases fidelity of signal transfer across the array. Further, given that may devices exhibit low dynamic resistance, maintaining impedance at a low level (e.g., below 50 Ohms) is desired. The examples described herein address one or more of these problems.

Some examples described herein provide a method for efficient routing of an N×N or N×M array, optimizing the arranged of elements for enhanced performance and operational efficiency.

Some examples described herein provide a design for low impedance in traces and impedance matching for active elements.

Some examples described herein provide a shielding design to maintain signal fidelity while mitigating cross-talk.

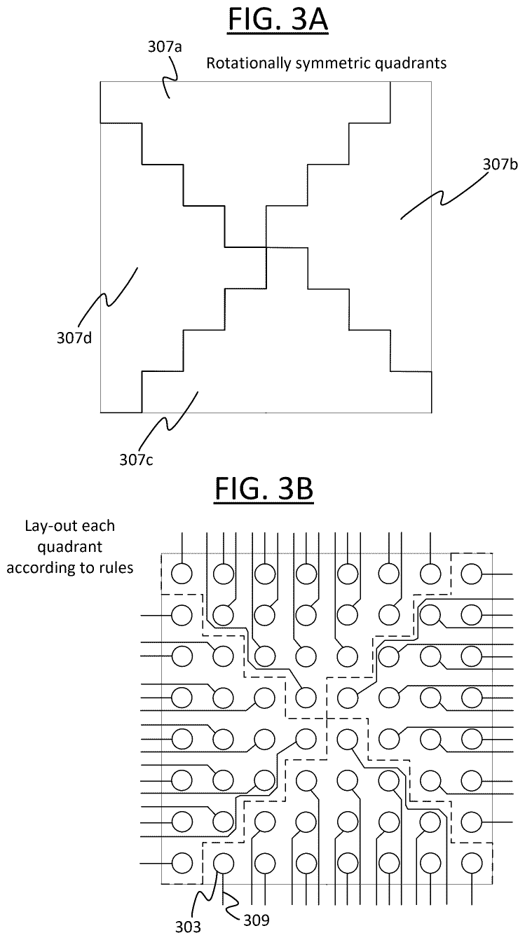

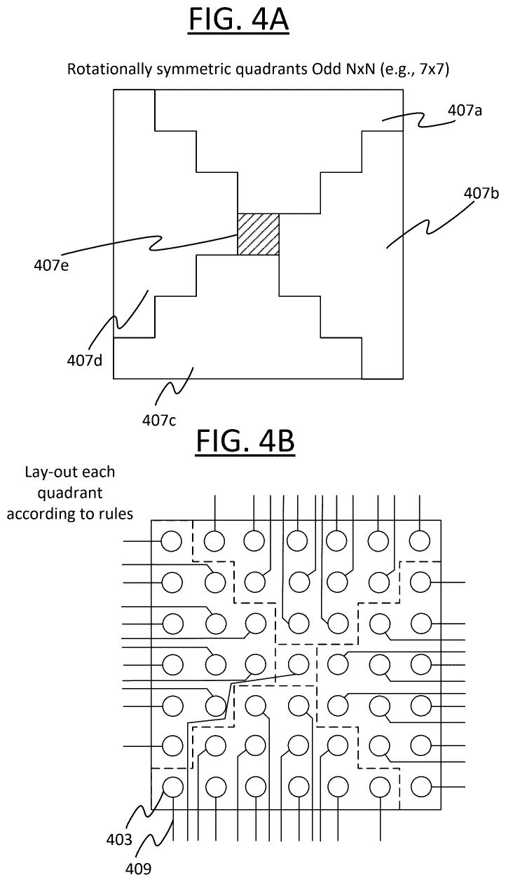

FIG. 3A, 3B, FIGS. 4A and 4B show a routing method for contacts of devices in an array to pads of an interposer (e.g., the pads situated at the edges of square 201). The method can be used to provide a high density of devices and contacts within the array. It should be noted that more than one layer of contacts may be routed on top of one another using the method of FIG. 3A, 3B, 4A and FIG. 4B.

A square (N×N) or rectangular (N×M) array may be split into rotationally symmetric quadrants 307a-d or 407a-d. As shown in FIGS. 4A and 4B, in some cases, e.g., in an N×N array where N is odd, there may be a central device 407e that is not included in any quadrant. In other examples, this central device 407e can be considered to be a part of each quadrant, such that the final device (the device in the inner most row of the quadrant) is the central device 407e.

In the square array (N×N) array, the array may be rotationally symmetric by rotating the array 90 degrees from a starting position. In the rectangular (N×M) array, the array may be rotationally symmetric by rotating the arrange 180 degrees from a starting position. FIGS. 3A and 3B show a square array of an even number of devices (i.e., an N×N array where N is even). FIGS. 4A and 4B show a square array of an odd number of devices (i.e., an N×N array where N is odd). FIGS. 3A, 3B, 4A and 4B show square arrays of devices (N×N), but simialr routing methods can be applied to rotationally symmetric N×M arrays of devices.

In FIG. 3B, an example device of the N×N array of devices (where N is even) is indicated at 303 and an example contact of the device is shown at 309. In FIG. 4B, an example device of the N×N array of devices (where N is odd) is indicated at 403 and an example contact of the device is shown at 409.

For the examples of both FIGS. 3B and 4B, the bottom quadrant (307c, 407c) may be routed as follows:
1) Route the devices of a 1st row (lowest row) of the bottom quadrant (307c,407c) downward to a pad of the interposer;
2) Route every subsequent row of the bottom quadrant (307c,407c) alternatingly (e.g. 2nd row left column, 3rd row right column, etc.) to a pad of the interposer;
3) Route the final device (i.e., the device in the inner most row of the bottom quadrant (307c, 407c)) either through to the leftmost (or rightmost) column to a pad of the interposer.

For the examples of both FIGS. 3B and 4B, the left quadrant (307d, 407d) may be routed as follows:
1) Route the devices of a 1st row (furthest left row) of the left quadrant (307c, 407c) left to a pad of the interposer;
2) Route every subsequent row of the left quadrant (307c, 407c) alternatingly (e.g. 2nd row top column, 3rd bottom column, etc.) to a pad of the interposer;
3) Route the final device (i.e., the device in the inner most row of the left quadrant (307c, 407c)) either through to the top most or bottom most column to a pad of the interposer.

For the examples of both FIGS. 3B and 4B, the top quadrant (307a, 407a) may be routed as follows:
1) Route the devices of a 1st row (top row) of the top quadrant (307a, 407a) upward to a pad of the interposer;
2) Route every subsequent row of the top quadrant (307a, 407a) alternatingly (e.g. 2nd row left column, 3rd row right column, etc.) to a pad of the interposer;
3) Route the final device (i.e., the device in the inner most row of the top quadrant (307a, 407a) either through to the leftmost (or rightmost) column to a pad of the interposer.

For the examples of both FIGS. 3B and 4B, the right orange quadrant (307b, 407b) may be routed as follows:
1) Route the devices of a 1st row (furthest right row) of the right quadrant (307b, 407b) (right to a pad of the interposer;
2) Route every subsequent row of the right quadrant (307b, 407b) alternatingly (e.g. 2nd row top column, 3rd bottom column, etc.) to a pad of the interposer;
3) Route the final device (i.e., the device in the inner most row of the right quadrant (307b, 407b)) either through to the top most or bottom most column to a pad of the interposer.

In general, the following may be performed for each quadrant: routing contacts of each device of a first row of devices in the quadrant in a first column comprising a straight line having the shortest route to a respective pad at an edge of the interposer, wherein the first row is closest to an outside edge of the rectangular array of devices; and then: a) routing a contact of each device of a next row of devices that is closest to the edge of the array to a column on a first side of the first column and adjacent and outside of the previous column on the first side of the device to a respective pad at the edge of the interposer; b) routing a contact of each device of a next row of devices closest to the edge of the array to a column on a second side of the first column and adjacent and outside of the previous column on the second side of the device to a respective pad at the edge of the interposer; repeating a) and b) until a device closest to the centre of the array of devices is reached, and then routing the contact for the device closest to the centre using a column furthest to the left or furthest to the right to a pad at the edge of the interposer.

In some examples, e.g., in FIG. 3B, there may be four devices that are closest to the centre of the array, such that four devices route a contact using a column furthest to the left or furthest to the right to a pad at the edge of the interposer. In other examples, e.g., in FIG. 4B where there is only one device in the centre of the array, only one device may route a contact using a column furthest to the left or furthest to the right to a pad at the edge of the interposer. In other words, step 3) of the above method may only need to be performed for one quadrant in an example where there an odd number of devices, such that only steps 1) and 2) are performed for the other quadrants (in order to avoid routing four contacts to the central device 407e).

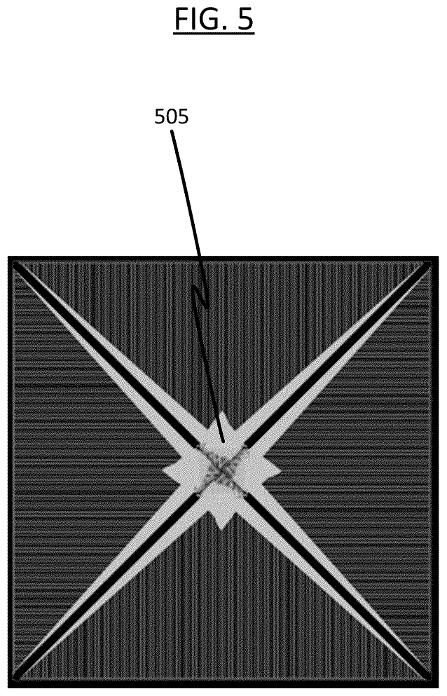

An illustrative example of routing of contacts for a 30×30 array 505 of devices is shown in FIG. 5.

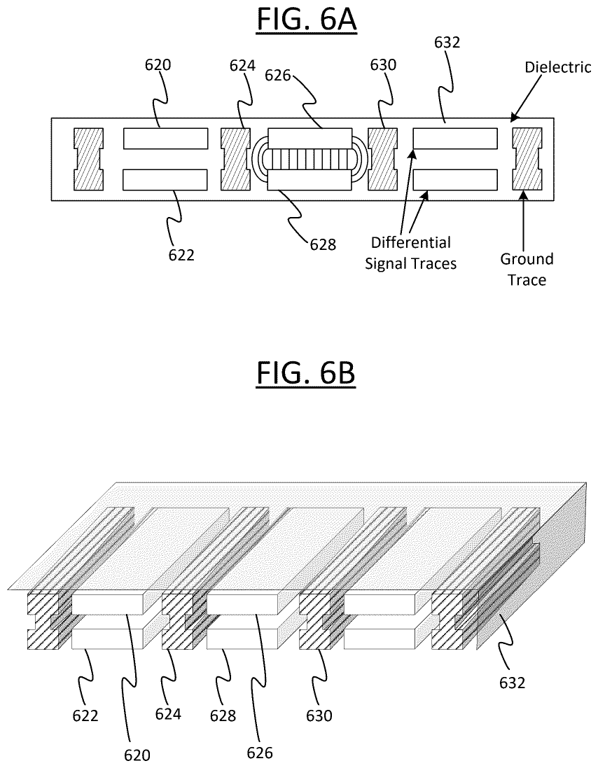

FIGS. 6A and 6B show a layout for differential signal traces of an interposer. This layout may be used for a differentially driven mode. The traces of the interposer can be used to connect to active elements (e.g., devices) of a device array, as discussed above. In the layout there is more than one layer of traces. Differential signal traces (e.g., differential signal trace 626 and 628, a pair of differential signal traces; or differential signal trace 620 and 622, a second pair of differential signal traces) are stacked such that differential signal traces within one pair are stacked on top of each other, in different layers. Each layer may comprise a metal layer. This reduces the impedance partly due to the width of the traces. Ground traces (e.g., ground trace 620, 624) provide shielding between each differential signal, reducing the cross-talk to adjacent traces. The field lines are illustrated in FIG. 6A for the pair of differential signal traces 626 and 628, showing that a good coupling to the other signal trace within the pair of differential signal traces can be achieved, as well as low cross talk to adjacent traces (e.g., to the pair of differential signal traces 620 and 622). A dielectric material 632 can be used to surround the traces.

It should be noted that the layout of the layers of FIGS. 6A and 6B can be combined with the routing method described above.

Although FIGS. 6A and 6B show pairs of differential signal traces (e.g., 626 and 628, or 620 and 622) stacked on top of one another, a similar layout may be used for situations for single-ended traces for an interposer. This layout may be used for a single-ended driven mode. For example, connection 620 may comprise a single metal line and connection 622 may comprise a ground connection. Similarly, connection 626 may comprise a single metal line and connection 628 may comprise a ground connection. Or, in other examples, connection 620 may comprise a ground connection and connection 622 may comprise a single metal line. Similarly, connection 626 may comprise a ground connection and connection 628 may comprise a single metal line.

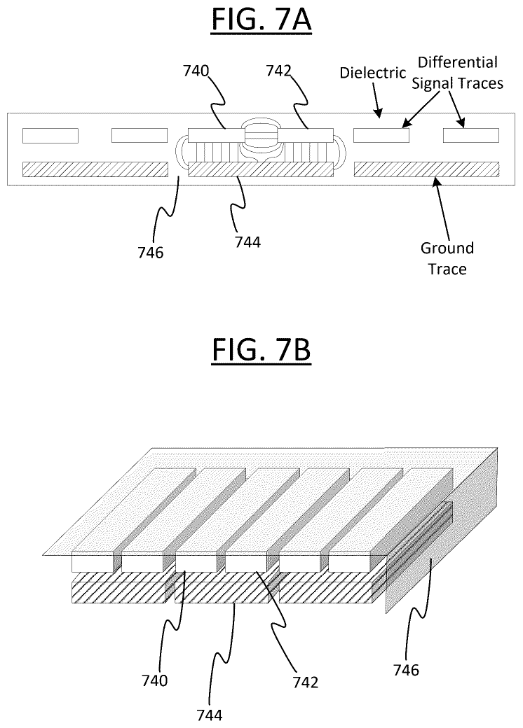

The layout of FIGS. 6A and 6B can be compared with FIGS. 7A and 7B, where differential signal traces 740 and 742 are positioned in a same layer and above ground trace 744. A dielectric material 646 surrounds the traces. Impedance in this layout will be higher, unless a very wide trace width is adopted, in which case the traces will require more space. Cross-talk is also problematic, as each trace can couple to adjacent traces that are not shielded. The field lines are illustrated in FIG. 7A for differential signal traces 740 and 742, showing not as good coupling to the other signal trace as in FIGS. 6A and 6B, as well as potential cross-talk to adjacent signal traces.

In other examples, a similar layout to FIGS. 7A and 7B could be used where connections 740 and 742 are used in a single-ended driven mode, where one connection is a ground connection and the other is a single-ended trace.

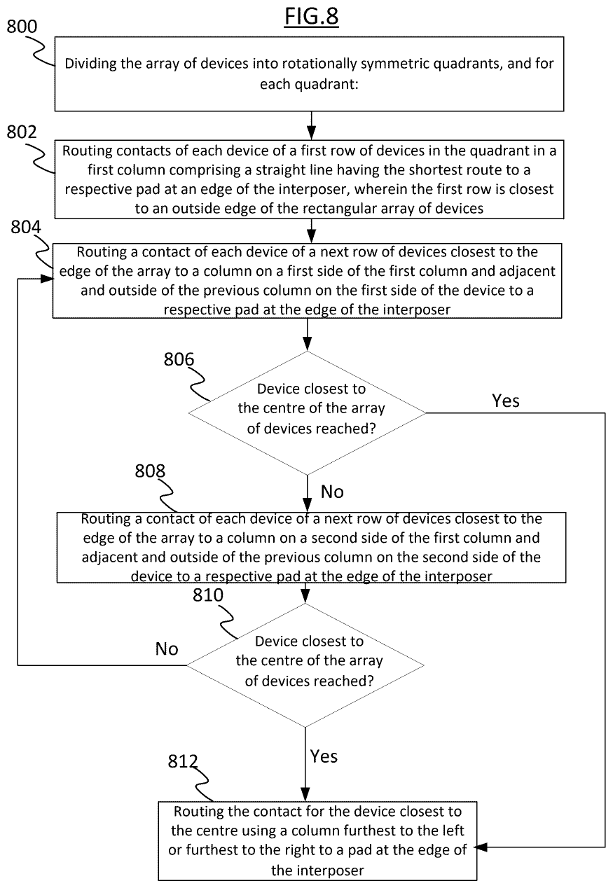

FIG. 8 illustrates a method of routing contacts of an array of devices to pads at an edge of an interposer.

At 800, the method comprises dividing the array of devices into rotationally symmetric quadrants. 802 to 812 can be performed for each rotationally symmetric quadrant.

At 802, the contacts of each device of a first row (the outermost, i.e. the furthest from the centre) of devices in the quadrant is routed in a straight line having the shortest route to a respective pad at an edge of the interposer, wherein the first row is closest to an outside edge of the rectangular array of devices.

804 comprises routing a contact of each device of a next row of devices closest to the edge of the array to a column on a first side of the first column and adjacent and outside of the previous column on the first side of the device to a respective pad at the edge of the interposer.

At 806, it is determined if a device in the quadrant closest to the centre of the array of devices has been reached. If yes, the method proceeds to 812. If no, the method proceeds to 808.

808 comprises routing a contact of each device of a next row of devices closest to the edge of the array to a column on a second side of the first column and adjacent and outside of the previous column on the second side of the device to a respective pad at the edge of the interposer. The second side is on the opposite side to the first side. The first side may be on the left and the second side on the right. Or, the first side may be on the right and the second side on the left.

At 810, it is determined if a device in the quadrant closest to the centre of the array of devices has been reached. If yes, the method proceeds to 812. If no, the method proceeds to 804.

At 812, the method comprises routing the contact for the device closest to the centre using a column furthest to the left or furthest to the right (furthest to the outside n the quadrant) to a pad at the edge of the interposer.

All of the disclosed operations or method steps, including those expressed in mathematical terms, may be implemented using suitable machine logic steps.

### Closing Remarks

It will be appreciated that the above embodiments have been disclosed by way of example only.

More generally, according to one aspect disclosed herein, there is provided an interposer comprising: a first pair of connections, wherein a first connection of the first pair of connections is positioned above a second connection of the first pair of connections; a second pair of connections, wherein a first connection of the second pair of connections is positioned above a second connection of the second pair of connections; a ground trace between the first pair of connections and the second pair of connections.

According to some examples, the first connection of the first pair of connections and the first connection of the second pair of connections are in a first metal layer, and the second connection of the first pair of connections and the second connection of the second pair connections are in a second metal layer. The first metal layer may be a different metal layer to the second metal layer.

According to some examples, the first pair of connections, the second pair of connections and the ground trace are surrounded by a dielectric material.

According to some examples, the first pair of connections comprises a first pair of differential signal traces such that the first connection of the first pair of connections comprises a first differential signal trace and the second connection of the first pair of connections comprises a second differential signal trace; and wherein the second pair of connections comprises a second pair of differential signal traces such that the first connection of the second pair of connections comprises a third differential signal trace and the second connection of the second pair of connections comprises a fourth differential signal trace.

According to some examples, the first pair of connections comprises a signal trace and a ground connection such that the first connection of the first pair of connections comprises a first signal trace and the second connection of the first pair of connections comprises a ground connection; and wherein the second pair of connections comprises a signal trace and a ground connection such that the first connection of the second pair of connections comprises a second signal trace and the second connection of the second pair of connections comprises a second ground connection.

According to some examples, the first pair of connections comprises a signal trace and a ground connection such that the first connection of the first pair of connections comprises a first ground connection and the second connection of the first pair of connections comprises a first signal trace; and wherein the second pair of connections comprises a signal trace and a ground connection such that the first connection of the second pair of connections comprises a second ground connection and the second connection of the second pair of connections comprises a second signal trace.

According to some examples, the first connection of the first pair of connections and the first connection of the second pair of connections are positioned at a same height in the interposer such that the first connection of the first pair of connections is parallel to the first connection of the second pair of connections; and wherein the second connection of the first pair of connections and the second connection of the second pair of connections are positioned at a same height in the interposer such that the second connection of the first pair of connections is parallel to the second connection of the second pair of connections.

According to some examples, the ground trace has a length extending to or beyond a bottom surface of the second connection of the first pair of connections and extending to or beyond a top surface of the first connection of the first pair of connections.

According to some examples, the first connection of the first pair of connections is positioned to increase coupling to the second connection of the first pair of connections.

According to some examples, the ground trace is positioned to reduce cross talk between the first pair of connections and the second pair of connections.

According to some examples, the interposer comprises a plurality of pads, wherein the first pair of connections and the second pair of connections are used to connect at least one device in a device array to the plurality of pads.

According to some examples, each connection of the first pair of connections and the second pair of connections connect a respective device in the device array to a respective pad.

According to some examples, each of the plurality of pads is positioned at one or more edges of the interposer.

According to some examples, the array of devices is positioned on top of the interposer.

According to some examples, the array of devices comprises a rectangular array of devices; wherein the first connection of the first pair of connections and the first connection of the second pair of connections are in a same layer of the interposer, the layer comprising a plurality of connections; wherein the pads of the plurality of pads are positioned at four edges of the interposer, and wherein the connections of the plurality of connections are routed such that, for each rotationally symmetric quadrant of the rectangular array of devices: a connection of each device of a first row of devices in the quadrant is routed in a first column comprising a straight line having the shortest route to a respective pad at an edge of the interposer, wherein the first row is closest to an outside edge of the rectangular array of devices; a connection of each device in a second row of devices closest to the edge of the array is routed to a column on a first side of the first column to a respective pad at the edge of the interposer; a connection of each device of a third row of devices closest to the edge of the array is routed to a column on a second side of the first column to a respective pad at the edge of the interposer; a connection of each device in each subsequent row of devices closest to the edge of the array is alternatingly routed in a column to the first side or to the second side, wherein the alternation depends on the row of devices and wherein connections for rows of devices closer to the centre of the array are routed to columns outside of the columns for connections further from the centre of the array.

According to some examples, for a quadrant, a device closest to the centre of the array has a connection routed using a column furthest to the left or furthest to the right of the quadrant to a pad at the edge of the interposer.

According to another aspect there is provided method of providing an interposer, the method comprising: providing a first pair of connections, wherein a first connection of the first pair of connections is positioned above a second connection of the first pair of connections; providing a second pair of connections, wherein a first connection of the second pair of connections is positioned above a second connection of the second pair of connections; providing a ground trace between the first pair of connections and the second pair of connections.

According to another aspect, there is provided a method of manufacturing any of the interposers described herein.

According to another aspect, there is disclosed a method of routing a rectangular array of devices to an interposer, the interposer comprising pads at four edges of the interposer, the method comprising: dividing the array of devices into rotationally symmetric quadrants; and for each rotationally symmetric quadrant: routing contacts of each device of a first row of devices in the quadrant in a first column comprising a straight line having the shortest route to a respective pad at an edge of the interposer, wherein the first row is closest to an outside edge of the rectangular array of devices; and then: a) routing a contact of each device of a next row of devices closest to the edge of the array to a column on a first side of the first column and adjacent and outside of the previous column on the first side of the device to a respective pad at the edge of the interposer; b) routing a contact of each device of a next row of devices closest to the edge of the array to a column on a second side of the first column and adjacent and outside of the previous column on the second side of the device to a respective pad at the edge of the interposer; repeating a) and b) until a device closest to the centre of the array of devices is reached, and then routing the contact for the device closest to the centre using a column furthest to the left or furthest to the right to a pad at the edge of the interposer.

According to some examples, the array of devices is positioned on top of the interposer.

According to some examples, the method is repeated for at least two layers of contacts of the interposer.

An interposer, as described above, may comprise any apparatus suitable for performing part, or all of, the features performed by an interposer.

Other variants or use cases may become apparent to a person skilled in the art once given the disclosure herein. The scope of the present disclosure is not limited by the above-described embodiments, but only by the accompanying claims.

1. An interposer comprising:
a first pair of connections, wherein a first connection of the first pair of connections is positioned above a second connection of the first pair of connections;
a second pair of connections, wherein a first connection of the second pair of connections is positioned above a second connection of the second pair of connections;
a ground trace between the first pair of connections and the second pair of connections.

2. The interposer of claim 1, wherein the first connection of the first pair of connections and the first connection of the second pair of connections are in a first metal layer, and wherein the second connection of the first pair of connections and the second connection of the second pair connections are in a second metal layer.

3. The interposer of claim 1, wherein the first pair of connections, the second pair of connections and the ground trace are surrounded by a dielectric material.

4. The interposer of claim 1, wherein the first pair of connections comprises a first pair of differential signal traces such that the first connection of the first pair of connections comprises a first differential signal trace and the second connection of the first pair of connections comprises a second differential signal trace; and
wherein the second pair of connections comprises a second pair of differential signal traces such that the first connection of the second pair of connections comprises a third differential signal trace and the second connection of the second pair of connections comprises a fourth differential signal trace.

5. The interposer of claim 1, wherein the first pair of connections comprises a signal trace and a ground connection such that the first connection of the first pair of connections comprises a first signal trace and the second connection of the first pair of connections comprises a ground connection; and
wherein the second pair of connections comprises a signal trace and a ground connection such that the first connection of the second pair of connections comprises a second signal trace and the second connection of the second pair of connections comprises a second ground connection.

6. The interposer of claim 1, wherein the first pair of connections comprises a signal trace and a ground connection such that the first connection of the first pair of connections comprises a first ground connection and the second connection of the first pair of connections comprises a first signal trace; and
wherein the second pair of connections comprises a signal trace and a ground connection such that the first connection of the second pair of connections comprises a second ground connection and the second connection of the second pair of connections comprises a second signal trace.

7. The interposer of claim 1, wherein the first connection of the first pair of connections and the first connection of the second pair of connections are positioned at a same height in the interposer such that the first connection of the first pair of connections is parallel to the first connection of the second pair of connections; and wherein the second connection of the first pair of connections and the second connection of the second pair of connections are positioned at a same height in the interposer such that the second connection of the first pair of connections is parallel to the second connection of the second pair of connections.

8. The interposer of claim 1, wherein the ground trace has a length extending to or beyond a bottom surface of the second connection of the first pair of connections and extending to or beyond a top surface of the first connection of the first pair of connections.

9. The interposer of claim 1, wherein the first connection of the first pair of connections is positioned to increase coupling to the second connection of the first pair of connections.

10. The interposer of claim 1, wherein the ground trace is positioned to reduce cross talk between the first pair of connections and the second pair of connections.

11. The interposer of claim 1, the interposer comprising a plurality of pads, wherein the first pair of connections and the second pair of connections are used to connect at least one device in a device array to the plurality of pads.

12. The interposer of claim 11, wherein each connection of the first pair of connections and the second pair of connections connect a respective device in the device array to a respective pad.

13. The interposer of claim 11, wherein each of the plurality of pads is positioned at one or more edges of the interposer.

14. The interposer of claim 11, wherein the array of devices is positioned on top of the interposer.

15. The interposer of any of claim 11, wherein the array of devices comprises a rectangular array of devices;
wherein the first connection of the first pair of connections and the first connection of the second pair of connections are in a same layer of the interposer, the layer comprising a plurality of connections;
wherein the pads of the plurality of pads are positioned at four edges of the interposer, and wherein the connections of the plurality of connections are routed such that, for each rotationally symmetric quadrant of the rectangular array of devices:
a connection of each device of a first row of devices in the quadrant is routed in a first column comprising a straight line having the shortest route to a respective pad at an edge of the interposer, wherein the first row is closest to an outside edge of the rectangular array of devices;
a connection of each device in a second row of devices closest to the edge of the array is routed to a column on a first side of the first column to a respective pad at the edge of the interposer;
a connection of each device of a third row of devices closest to the edge of the array is routed to a column on a second side of the first column to a respective pad at the edge of the interposer;
a connection of each device in each subsequent row of devices closest to the edge of the array is alternatingly routed in a column to the first side or to the second side, wherein the alternation depends on the row of devices and wherein connections for rows of devices closer to the centre of the array are routed to columns outside of the columns for connections further from the centre of the array.

16. The interposer according to claim 15, wherein, for a quadrant, a device closest to the centre of the array has a connection routed using a column furthest to the left or furthest to the right of the quadrant to a pad at the edge of the interposer.

17. A method of providing an interposer, the method comprising:
providing a first pair of connections, wherein a first connection of the first pair of connections is positioned above a second connection of the first pair of connections;
providing a second pair of connections, wherein a first connection of the second pair of connections is positioned above a second connection of the second pair of connections;
providing a ground trace between the first pair of connections and the second pair of connections.

18. A method of routing a rectangular array of devices to an interposer, the interposer comprising pads at four edges of the interposer, the method comprising:
dividing the array of devices into rotationally symmetric quadrants; and for each rotationally symmetric quadrant:
routing contacts of each device of a first row of devices in the quadrant in a first column comprising a straight line having the shortest route to a respective pad at an edge of the interposer, wherein the first row is closest to an outside edge of the rectangular array of devices; and then:
a) routing a contact of each device of a next row of devices closest to the edge of the array to a column on a first side of the first column and adjacent and outside of the previous column on the first side of the device to a respective pad at the edge of the interposer;
b) routing a contact of each device of a next row of devices closest to the edge of the array to a column on a second side of the first column and adjacent and outside of the previous column on the second side of the device to a respective pad at the edge of the interposer;
repeating a) and b) until a device closest to the centre of the array of devices is reached, and then routing the contact for the device closest to the centre using a column furthest to the left or furthest to the right to a pad at the edge of the interposer.

19. The method according to claim 18, wherein the array of devices is positioned on top of the interposer.

20. The method according to claim 18, wherein the method is repeated for at least two layers of contacts of the interposer.
